(19) United States
(12) Patent Application Publication
(10) Pub. No.: US 2013/0182745 A1
(43) Pub. Date: Jul. 18, 2013

(54) LOW-PROFILE TEMPERATURE SENSOR PROBE

(71) Applicant: Therm-O-Disc, Incorporated, Mansfield, OH (US)

(72) Inventors: Amy Hertel, Rothbury, MI (US); Xue Gang, ShenZhen (CN)

(73) Assignee: Therm-O-Disc, Incorporated, Mansfield, OH (US)

(21) Appl. No.: 13/733,236

(22) Filed: Jan. 3, 2013

(30) Foreign Application Priority Data
Jan. 13, 2012 (CN) 2012100103422

(51) Int. Cl. G01K 7/16; G01R 3/00

(52) U.S. Cl. CPC G01K 7/16; G01R 3/00
USPC 374/185; 29/595

(57) ABSTRACT

A low-profile temperature sensor probe is disclosed as including a probe circuit subassembly having a temperature sensing thermistor, the subassembly being overmolded with a durable insulating material to form the probe body. The probe body forms a connector block portion and a flexible extension portion. The flexible extension portion enables the sensor probe to conform to the surface of the object to be sensed without undue strain on the components. The thermistor element is located in a protective pocket and positioned relative the probe body to ensure direct contact with the object to be sensed. The connector block is configured to accommodate a standard plug-in type electrical connector.

### CROSS-REFERENCE TO RELATED APPLICATIONS

This application claims the benefit and priority of Chinese Patent Application Number 2012100103422 filed Jan. 13, 2012. The entire disclosure of the above application is incorporated herein by reference.

### FIELD

The present disclosure relates to temperature sensors and, more particularly, to a durable, flexible, low-profile temperature sensor probe.

### BACKGROUND AND SUMMARY

This section provides background information related to the present disclosure which is not necessarily prior art.

In rechargeable energy storage systems, particularly those used in automotive vehicle applications, it is important to know the temperature of the batteries so that system performance can be optimized and conditions adverse to the system, such as charging the battery at low temperatures, can be avoided. Consequently, temperature sensors are used to sense the battery temperature during vehicle operation.

The battery pack is typically comprised of a plurality of individual power cells which are tightly packed together to minimize space. In this regard, one or more temperature sensors are provided in the battery. The temperature sensor probe preferably has a low profile and can be tightly integrated into the battery pack, sandwiched in between the cells, since space is at a premium in the vehicle. The temperature sensor probe preferably promotes good surface contact area with the object to be sensed to enable it to accurately and quickly sense the battery temperature.

Because multiple sensors are used for each battery pack, the sensor is preferably cost effective to manufacture.

Prior low-profile temperature sensor probe designs incorporated a thermistor comprising traces on a printed circuit board (PCB) coated with a insulating material and having a connector block attached at one end of the board. However, the prior designs did not prove reliable and were susceptible to damage. For example, the PCB is brittle and could not effectively and reliably withstand routine handling without damage. Additionally, the insulating coating did not provide adequate electrical insulation and effective isolation from ambient conditions like temperature and humidity.

As shown in the figures, the temperature sensor probe of the disclosure includes a probe circuit subassembly having a temperature sensing thermistor element that is overmolded with a durable insulating material to form the sensor probe body. The sensor probe body forms a connector block portion and a flexible extension portion. The thermistor element includes an NTC bead having a pair of bead lead wires that are electrically spliced to a pair of lead wires that are, in turn, connected to a pair of terminals. The bead lead wires are protected by a PTFE cover. The electrical splices between the bead lead wires and the lead wires are electrically isolated and protected by shrink wrap tubing that covers the entire electrical connection. The probe circuit subassembly is then overmolded with a durable, resilient plastic that encompasses the wires of the probe circuit subassembly to protect them and create the flexible extension portion. The flexible extension portion enables the sensor probe to conform to the surface of the object to be sensed without putting an undue a strain on the components of the probe circuit subassembly. The thermistor element remains exposed to contact with the object to be sensed. The connector block is configured to accommodate a plug-in-type electrical connector.

The temperature sensor probe and, particularly, its probe circuit subassembly, is fully insulated electrically, thermally and from other ambient conditions, such as humidity and dirt. The temperature sensor probe is durable yet exhibits flexibilty. The sensor provides an integral connector for connection to a wiring harness, controller, or the like. The low profile configuration of the temperature sensor probe makes it ideal for applications requiring a small space claim.

As shown in the Figures the temperature sensor probe assembly is suitable for use in measuring temperatures in a rechargeable energy storage system used in an automobile. The temperature sensor probe is flexible to allow for expansion and contraction of the cells and/or cell modules during operation, and to closely form to the surface of the cells and/or cell modules. At the same time, the sensor probe provides a robust means to electrically connect the sensor probe to a wiring harness and/or a control module or other electronics in the vehicle.

In one aspect, the disclosure provides a low-profile temperature sensor probe comprising a probe circuit encapsulated by an integral dielectric body that is molded over the probe circuit. The probe circuit comprises a thermistor element including a pair of insulated thermistor leads, a first protective tubular material surrounding both of the thermistor leads, and a pair of insulated lead wires having a first end and a second end, each lead wire electrically connected at the first end to a respective one of the thermistor leads, thereby creating two electrical splice connections between insulated thermistor leads and the insulated lead wires. In addition, a pair of terminals are included, and each lead wire is electrically connected at the second end to a respective one of the terminals. A first heat-shrinkable, dielectric tubular material surrounding one of the pair of electrical splice connections, the tubular material isolating the electrical splice connections from each other, and a second heat-shrinkable, dielectric tubular material surrounding both of the pair of electrical splice connections and the first tubular material are further included. The body comprises a connector block portion and an extension portion, the connector block portion housing the electric terminals and being configured to accommodate a plug-in type electrical connector, and the extension portion extending from a first end proximate to the connector block portion generally linearly along a longitudinal axis of the sensor probe to a second end distal from the connector block portion. Also, the thermistor element is exposed near the distal end of the extension portion to enable it to directly contact an object to be sensed for temperature by the sensor probe.

In other aspects, the extension portion further comprises an aperture near the distal end of the extension portion and the thermistor element is located in the aperture. Also, the low-profile temperature sensor probe includes a support cover installed in the aperture that forms at least a portion of a pocket surrounding the thermistor element and positions the thermistor element relative to a first side surface of the extension portion, for example, so that it slightly protrudes from the first side surface of the extension portion. In still other aspects, the low-profile temperature sensor probe body and support cover comprise a resilient thermoplastic material.

In another aspect, the disclosure provides a low-profile temperature sensor probe including a probe circuit substantially encompassed by an integral, resilient, dielectric body. The probe circuit comprises a thermistor having two first insulated lead wires, two second insulated lead wires, and a resilient protective cover located around the first insulated lead wires. Each first lead wires is electrically connected to a respective second lead wire to create two first lead wire/second lead wire connections. The first lead wire/second lead wire connections being electrically isolated from one another. The body has an extension portion that generally extends along a longitudinal axis of the sensor probe from a first proximal end to a second distal end, and the extension portion comprises a first surface and an aperture near its distal end. The thermistor is located in the aperture and positioned relative to the first surface such that it directly contacts an object to be sensed for temperature when the sensor probe is in use.

In yet another aspect, the disclosure provides a method for manufacturing a low-profile temperature sensor including providing a thermistor element having a thermistor bead and two insulated thermistor leads. The thermistor leads are surrounded with a tubular PTFE material. A pair of insulated lead wires is provided, each having a first end and a second end. Each thermistor lead is electrically connected to the first end of a corresponding lead wire to create a pair of first electrical connections. One thermistor lead/lead wire connection is surrounded with a first heat shrinkable, dielectric, tubular material, and the other thermistor lead/lead wire connection and the first heat shrinkable, dielectric, tubular material is surrounded with a second heat shrinkable, dielectric, tubular material. A pair of terminals are provided and each is electrically connected to a second end of a corresponding lead wire to create a pair of second electrical connections. The first and second electrical connections and the lead wires are encompassed with a dielectric, thermoplastic material to create a flexible extension portion including an aperture near a distal end of the extension portion with the thermistor element located within the aperture. A support element is inserted in the aperture to position the thermistor bead relative to a first surface of the extension portion such that the thermistor bead protrudes from the first surface.

In still another aspect, a method for manufacturing a low-profile temperature sensor with a circuit including a thermistor element and lead wires involves surrounding two insulated thermistor leads of the thermistor element with a protective, resilient material, then electrically connecting each of the two insulated thermistor leads of the thermistor element to a corresponding one of two lead wires to create two thermistor lead/lead wire connections. The thermistor lead/lead wire connections are electrically isolated from one another. Then, overmolding the thermistor lead/lead wire connections with a resilient, dielectric thermoplastic material to encompass thermistor lead/lead wire connections and forming a body having an extension portion including a first surface and an aperture in which the thermistor element is located. Finally, the thermistor element is positioned relative to the first surface such that the thermistor element protrudes from the first surface.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 shows a perspective view of the low-profile temperature sensor probe of the disclosure;

FIGS. 2(A) through 2(D) show various orthogonal views of the low-profile temperature sensor probe of FIG. 1.

FIG. 3 shows a perspective view of a sensor probe subassembly of the low-profile temperature sensor probe of the disclosure;

FIGS. 4(A) through 4(E) schematically depict various stages of construction for the sensor probe subassembly shown in FIG. 3;

FIG. 5(A) shows a perspective view of the support bracket for the low-profile temperature sensor probe of the disclosure;

FIG. 5(B) shows a cross-sectional view of the support bracket taken along the line 5B-5B of FIG. 5(A);

FIGS. 6(A) through 6(C) show various orthogonal views of the terminal for use with the sensor probe subassembly shown in FIG. 3;

FIGS. 7 through 9 illustrate steps in an overmolding process that can be employed in the manufacture of the low-profile temperature sensor probe of the disclosure;

FIG. 10 depicts installing a protective cover for the thermistor element in an aperture of the low-profile temperature sensor probe of the disclosure;

FIG. 11 shows an enlarged, partial cross-sectional view of a portion of the low-profile temperature sensor probe of the disclosure along the line 11-11 of FIG. 10;

FIG. 12 depicts a schematic representation of a rechargeable energy storage device incorporating the low-profile temperature sensor probe of the disclosure; and

FIG. 13 shows and enlarged schematic view of Detail 13 of FIG. 12.

Corresponding reference numerals indicate corresponding parts throughout the several views of the drawings.

### DETAILED DESCRIPTION

Example embodiments will now be described more fully with reference to the accompanying drawings.

As illustrated in the Figures, the disclosure provides a robust, compact, fast responding, fully insulated temperature sensor probe 10 with an integral connector block portion 12 and having a low profile. Because the sensor probe 10 has a low profile and small footprint, it is suitable for use in applications where space is at a premium. In one anticipated application, the sensor probe can be compressed between the battery cells in a battery pack of a rechargeable energy storage system.

The sensor probe 10 employs a fast-response-time, negative temperature coefficient (NTC) thermistor element 14. The thermistor element 14 is part of a probe circuit subassembly 16 that also includes insulated and covered lead wires 38, 40 and connection terminals 42. The probe circuit subassembly 16 is encapsulated in an integral dielectric housing or body 18 that is molded over the probe circuit subassembly 16. As shown, the thermistor element 14 nevertheless remains exposed at an end of the sensor probe 10 to enable it to directly contact an object to be sensed for temperature.

The overmolded dielectric body 18 of the sensor probe 10 makes the probe resilient, flexible and/or pliable to enable the sensor probe 10 to adapt to surface contours of the sensed object and to promote the direct contact between the sensor probe and the object to be sensed without creating undesirable strain on the probe circuit subassembly 16 or its components. In this regard, the sensor probe 10 can move or flex with the object while still maintaining good surface contact, such as in situations where the object expands and/or contracts with temperature changes.

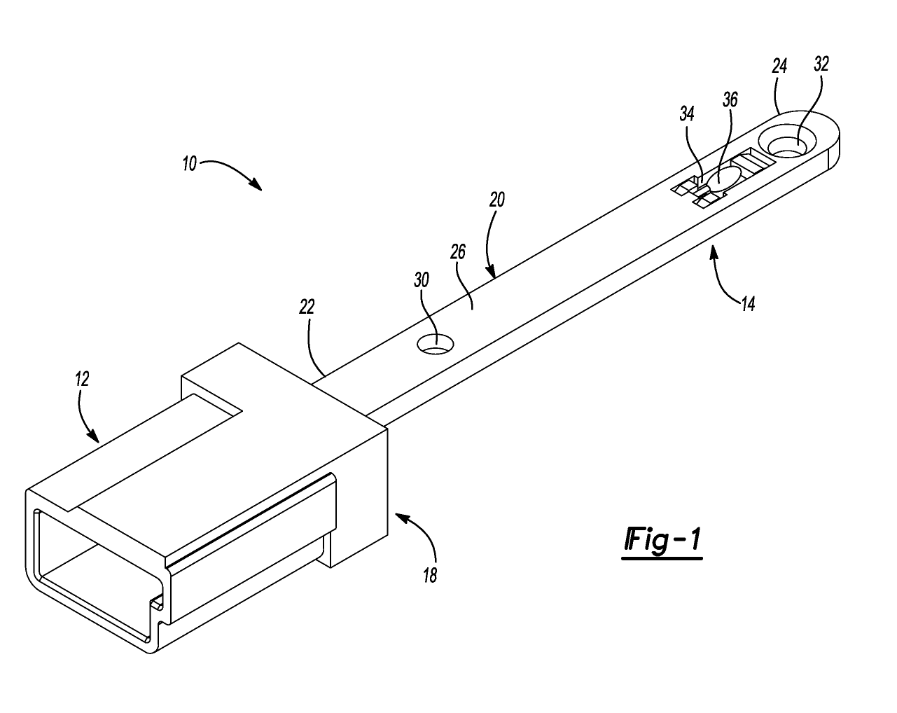

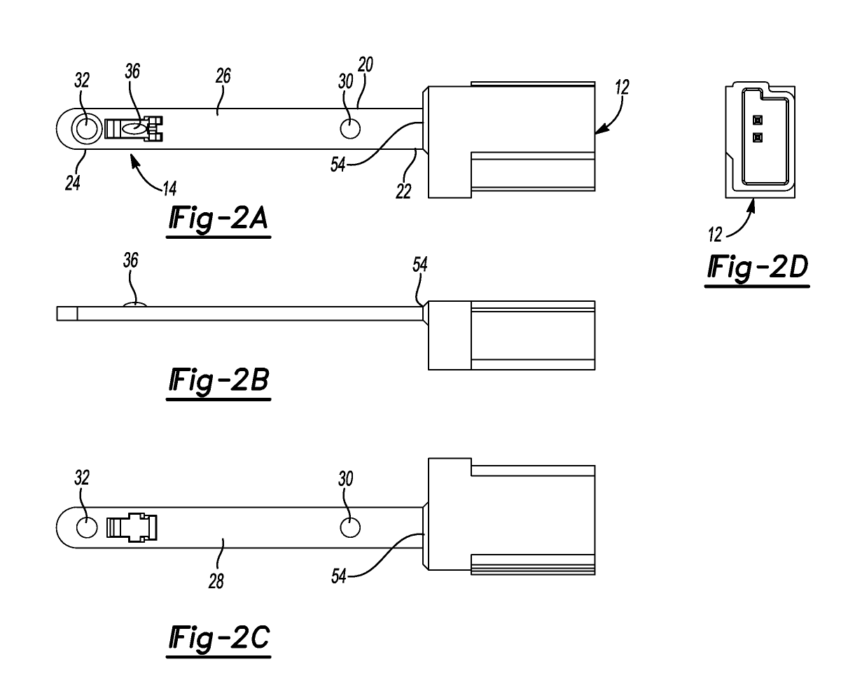

One embodiment of the low profile temperature sensor probe 10 of the disclosure is illustrated in the figures. Referring to FIGS. 1 and 2(A) through 2(D), the sensor probe device 10 comprises a probe circuit subassembly 16 that is encapsulated by an overmolded dielectric body 18. As shown, the sensor probe device 10 generally includes a connector block portion 12 and a flexible probe extension portion 20.

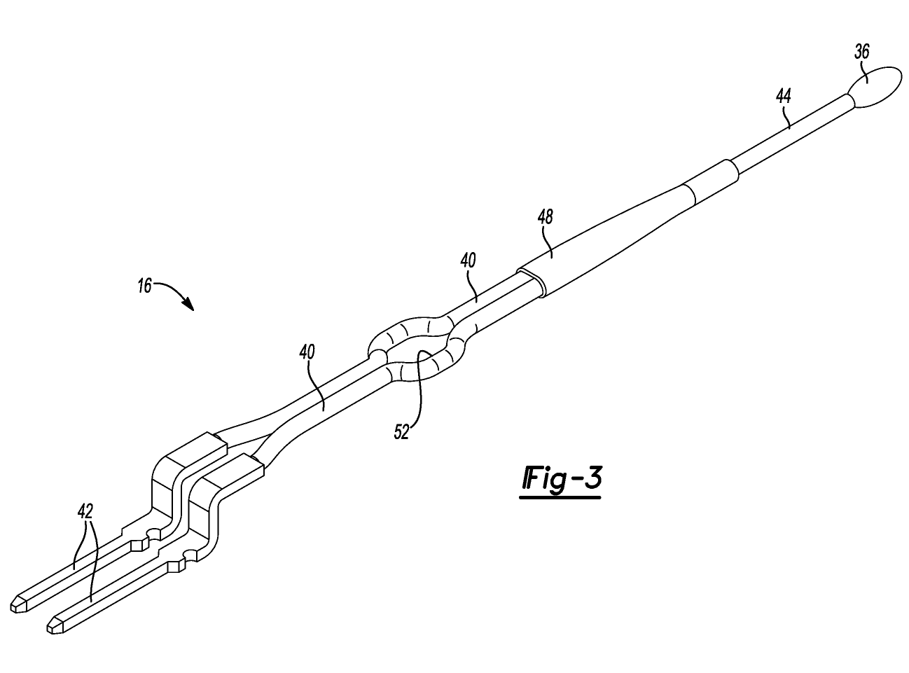

The connector block portion 12 is configured to accommodate a plug-in type electrical connector, such as would be part of a standard wiring harness in an automobile or other application, for example, to connect the sensor probe 10 to a circuit for monitoring a condition of the sensor probe which is correlated to a temperature value. The connector block portion 12, therefore, houses the electric terminals 42 (best seen in FIGS. 3 and 6(A) through 6(C)) of the probe circuit subassembly 16. As shown in FIGS. 1 and 2(A) through 2(D), the connector block portion 12 comprises a connector receptacle, such as for a JST connector that is well-known in the art. As will be appreciated by persons having ordinary skill, the connector block 12 may be configured to accommodate any of a variety of standard plug-in-type connectors that are well-known in the art.

The flexible extension portion 20 of the sensor probe device 10 is shown to comprise a long, narrow, generally rectangularly-shaped feature. The extension portion 20 extends from a first end 22 proximate to the connector block portion 12 generally linearly along a longitudinal axis of the device to a second end 24 distal from the connector block portion 12. In the embodiment illustrated in the figures, the extension portion 20 has a first (front) side surface 26 and a second (back) side surface 28, and a plurality of apertures 30, 32 extending through the extension portion 20 from the first side surface 26 to the second side surface 28. The apertures 30, 32 can be operable to accommodate locating features and/or mounting fasteners (not shown) that can be used locate and/or secure the sensor probe device 10 in place when it is installed.

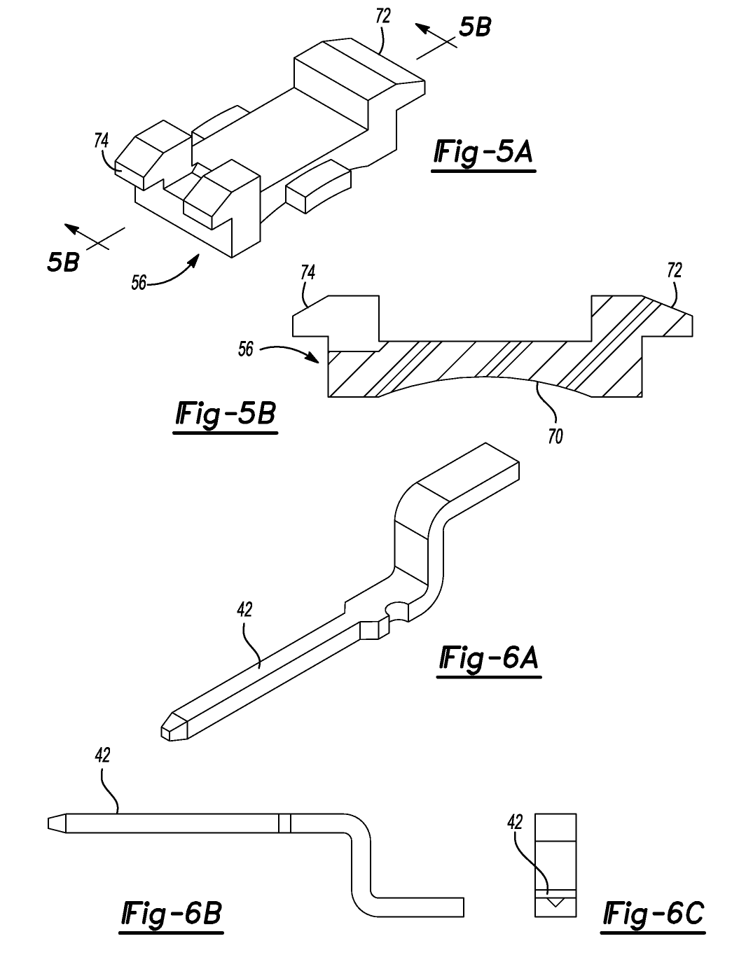

In addition to the locating or mounting apertures 30, 32, the extension portion includes an aperture 34 near the distal end 24 of the extension portion 20 in which the thermistor element 14 is located. A support cover 56 (FIG. 5(A)) that is installed in the aperture 34, in combination with the body 18, forms a protective pocket that surrounds and positions the thermistor element 14, and particularly the thermistor bead 36. In addition, the support cover 56 helps position the thermistor bead 36 relative to the surface 26 of the extension portion 20, as shown in FIGS. 2(A) and 2(B), for example.

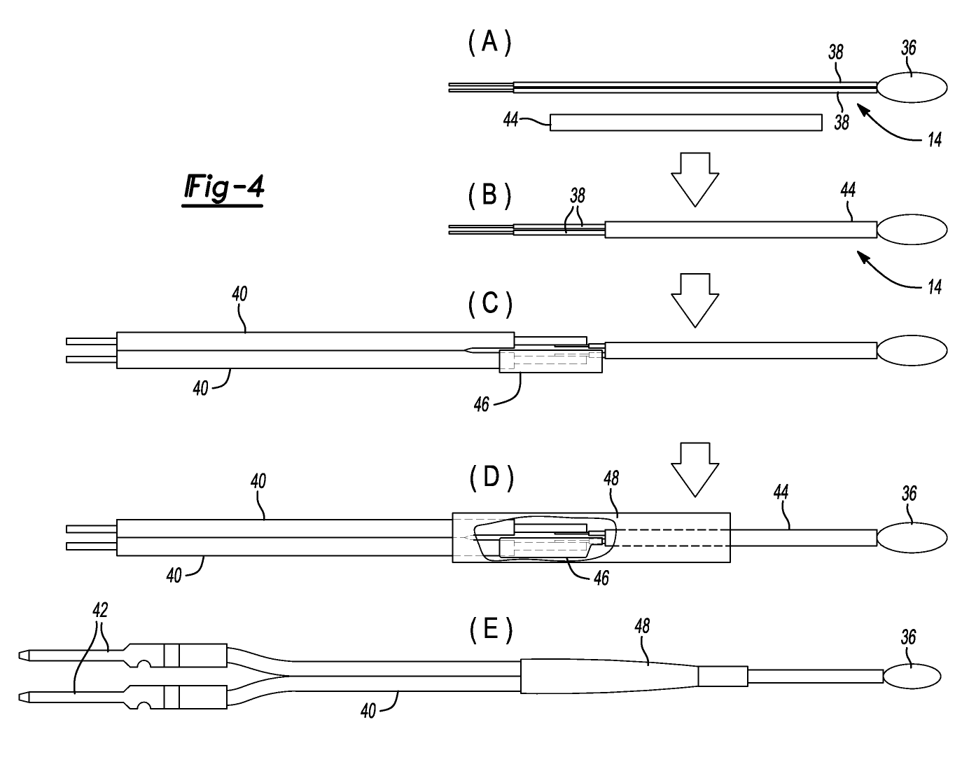

FIGS. 3, 4(A) through (E) and 6(A) illustrate the probe circuit subassembly 16 and its components. The probe circuit subassembly 16 generally comprises the thermistor element 14, including a pair of thermistor leads 38, a pair of insulated lead wires 40 respectively connected to the pair of thermistor leads 38, and a pair of terminals 42 respectively connected to the pair of lead wires 40. A durable, PTFE tubing 44, such as Teflon™ tubing, is applied over the thermistor leads 38 to provide a protective covering so that the thin gauge leads are not damaged during the manufacturing process. In addition, shrink tubing 46, 48 is applied over the electrical splice connections between the thermistor leads 38 and the lead wires 40 to both isolate the connections and provide a protective covering.

The construction of the probe circuit subassembly 16 may be understood with reference to FIG. 3, and further reference to FIGS. 4(A) through (E). As shown in FIG. 4(A), the thermistor element 14 comprises a thermistor bead 36 and a pair of insulated thermistor leads 38. The ends of the thermistor leads 38 opposite to the thermistor bead 36 are stripped of insulation and tinned in preparation for soldering to the respective lead wires 40. A PTFE tubing 44 is applied over and around the portion of the thermistor leads 38 up to the location of the thermistor bead 36 to provide a durable protective cover that reinforces the thermistor leads 38 and enables the thermistor element 14 to resist inadvertent damage during the manufacturing process. At FIG. 4(B), the thermistor element 14 with the PTFE tubing 44 already applied is shown.

As shown in FIG. 4(C), each of the pair of lead wires 40 is soldered to a respective one of the thermistor leads 38. A first heat shrinkable dielectric tubing 46 is then applied over and around one of the thermistor lead/lead wire connections in order to electrically isolate the two electrical connections. A second heat shrinkable dielectric tubing 48 is thereafter applied over and around both of the thermistor lead/lead wire connections together, including the first isolated connection, as illustrated in FIG. 4(D). As shown in FIG. 4(D), the second heat shrinkable tubing 48 extends over a portion of the PTFE tubing 44 previously applied, and to the insulation covering the lead wires 40. Consequently, the second heat shrinkable tubing 48 completely covers and insulates the entire area of the thermistor lead/lead wire connections.

Finally, the pair of terminals 42 (see FIG. 6(A) through 6(C)) are soldered to the respective ends of the lead wires 40 as shown in FIG. 4(E), completing the probe circuit subassembly 16.

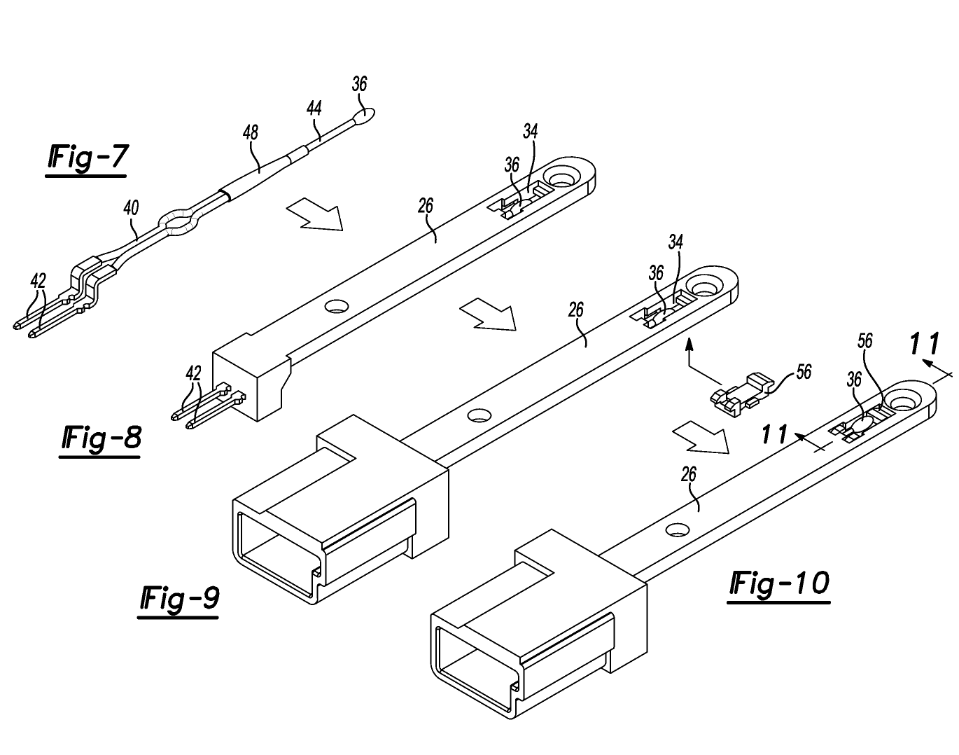

Referring to FIGS. 7-9, after the probe circuit subassembly 16 is assembled, it is overmolded in an injection molding process, for example, to produce the robust, low-profile temperature sensor probe 10 of the disclosure. The probe circuit subassembly 16 can be inserted into a mold cavity (not shown) that positions and locates the features of the probe circuit subassembly 16, like the thermistor element bead 36 and the terminals 42, relative to the features of the to-be-overmolded sensor probe body 18, like the extension portion 20 and the connector block portion 12. Prior to the overmolding process, the lead wires 40 of the probe circuit subassembly 16 can be formed to create an aperture 52, as shown in FIG. 7, to accommodate the locating or mounting aperture(s) 30, 32 included in the extension portion 20. The overmolding process forms the body 18 of the sensor probe 10, including creating the connector block portion 12 over the terminals 42. In addition, the overmolded body 18 completely encompasses and insulates the probe circuit subassembly 16, while at the same time locating the thermistor bead 36 in the aperture 34 of the extension portion 20. The result achieved is a tough, resilient, insulating body 18 formed over the probe circuit subassembly 16.

Referring to FIG. 2 and again to FIGS. 8 and 9, while the overmolded body 18 is generally resilient, its design configuration also results in line 54 located at the proximal end 22 of the extension portion 20 where it meets the connector block portion 12 where the body 18 may flex. Relative to the probe circuit subassembly 16, the configuration of the body 18 places the line 54 at a location such that it does not coincide or intersect with a solder connection in the probe circuit subassembly 16, such as the solder connections between the lead wires 40 and the terminals 42, for example. As shown in FIG. 2, the line 54 is, instead, located where only the lead wires 40 pass through. Consequently, any flexure along the line 54 does not tend to strain the solder connections of the probe circuit subassembly 16. Moreover, the resilience of the molded sensor probe body 18 resists damage due to handling, such as fracture of the connector block portion 12 or failure of the insulation covering the wires of the probe circuit subassembly 16.

The overmolding can be accomplished in a single molding operation or in multiple molding operations, as depicted in FIGS. 7-9. When a two-step overmolding procedure is employed, the first molding step can substantially create the extension portion 20 of the sensor probe device 10 (FIG. 8) and the second molding step can create the connector block portion 12 to complete the sensor probe body 18 (FIG. 9). A suitable material for molding the sensor probe body 18 is nylon (PA66), and particularly a 15% glass-filled nylon injection molding material.

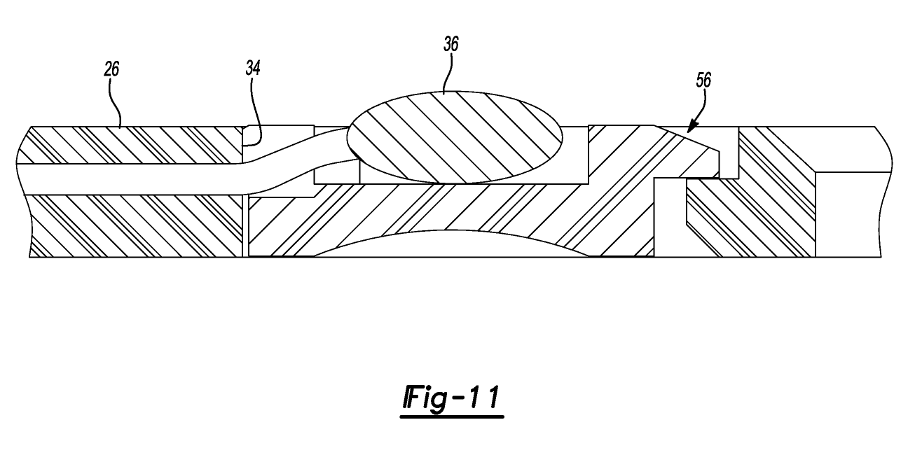

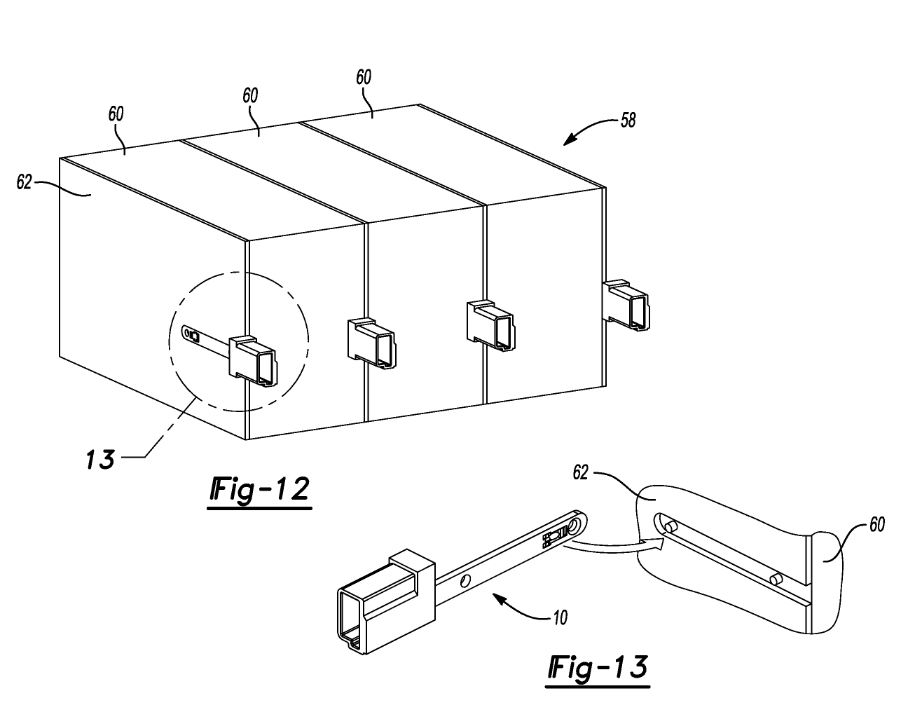

As shown in FIGS. 2, 5 and 9-11, a support cover 56 is included at the aperture 34 of the extension portion 20 to help create the pocket that protects and positions the thermistor bead 36 relative to the upper surface 26 of the extension portion 20. As a result, a fast and accurate temperature response can be achieved. In this regard, the thermistor bead 36 preferably protrudes slightly from of the pocket, above the upper surface 26 of the extension portion 20 as shown in FIGS. 2(B) and 11. As such, the thermistor element 14 is insured to achieve direct contact with the surface of the object to be sensed when the sensor probe 10 is installed. The support cover 56, however, is made from a resilient material and therefore provides some give or flexing to prevent the thermistor bead 36 from being compressed between the support cover 56 and the surface of the object to be sensed.

In particular, for example, as shown in FIG. 5(B), the support cover 56 includes a bridge portion 70 on which the thermistor bead 36 is supported. The bridge portion 70 extends between opposing clip supports 72, 74. The clip supports 72, 74 engage the aperture 34 in order to mount the support cover 56 to the extension portion 20. When the sensor probe 10 is in an uninstalled condition, the bridge portion 70 supports the thermistor bead 36 such that it protrudes above the upper surface 26 of the extension portion 20, as described. However, when the sensor probe 10 is in an installed condition, and the thermistor bead 36 is in contact with the surface to be sensed, the bridge portion 70 is able to flex, as necessary, to allow the thermistor bead 36 to move back into the pocket. In this condition, then, the bias of the support cover 56 against the thermistor bead 36 ensures that contact is maintained between the thermistor bead 36 and the surface to be sensed.

In the schematic illustrations of FIGS. 12 and 13, one anticipated application for the low-profile temperature sensor probe 10 of the disclosure in a battery pack of a rechargeable energy storage system is shown. As shown in FIG. 12, a battery pack 58 includes a plurality of battery sections or modules 60 each comprising a plurality of individual power cells that are closely positioned adjacent to one another. Individual modules 60 are separated by separator plates 62. The low-profile sensor probe 10 of the disclosure is particularly suited for mounting in direct contact with the modules 60 of the battery pack 58. For example, as shown in FIGS. 12 and 13, the sensor probe 10 can be mounted to the separator plates 62 included between the modules 60. The thermistor bead 36 of the sensor probe 10 is thereby exposed to and compressed against the module 60, placing it in direct contact with a surface of the module 60. As such, a reliable and quick temperature sensing response is achieved. Moreover, the sensor probe 10 can be constructed to accommodate both a left-handed and right-handed installation, as shown in FIG. 12.

In an alternative embodiment of the sensor probe 10 of the disclosure, the overmolded body 18 does not have to include an integral connector block portion 12. For example, a completed sensor probe 10 body 18 could be configured as shown in FIG. 8, comprising the probe circuit subassembly with the overmolded extension portion 20 and the terminals 42 exposed. With such a sensor probe construction, then, connection to a wiring harness, controller, or the like could be made with a push-on-type terminal connector, quick-connect terminal connector, and/or spring-type contact or clip.

In still another alternative embodiment of the sensor probe 10 of the disclosure, the sensor probe 10 does not require any terminals 42. Instead, the lead wires 40 of the sensor probe 10 are lengthened so they extend from the sensor probe's overmolded body 18. In such a case, the length of the lead wires 40 could vary as required for a particular wiring arrangement of the sensor probe. For example, the lead wires 40 could extend in length so they may be directly connected to a controller monitoring the condition of the sensor probe. Alternatively, the lead wires of one or more sensor probe(s) could be wired to a common connector for the sensor probe(s) and/or other electronic components of the apparatus in which the sensor probe is installed. Still further, the lead wires could, themselves, form part of a wiring harness.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A low-profile temperature sensor probe comprising:
a probe circuit encapsulated by an integral dielectric body that is molded over the probe circuit;
the probe circuit comprising:
a thermistor element including a pair of insulated thermistor leads;
a first protective tubular material surrounding both of the thermistor leads;
a pair of insulated lead wires having a first end and a second end, each lead wire electrically connected at the first end to a respective one of the thermistor leads, thereby creating two electrical splice connections between insulated thermistor leads and the insulated lead wires;
a pair of terminals, each lead wire electrically connected at the second end to a respective one of the terminals;
a first heat-shrinkable, dielectric tubular material surrounding one of the pair of electrical splice connections, the tubular material isolating the electrical splice connections from each other; and
a second heat-shrinkable, dielectric tubular material surrounding both of the pair of electrical splice connections and the first tubular material;
the body comprising a connector block portion and an extension portion, the connector block portion housing the electric terminals and being configured to accommodate a plug-in type electrical connector, the extension portion extending from a first end proximate to the connector block portion generally linearly along a longitudinal axis of the sensor probe to a second end distal from the connector block portion; and
wherein the thermistor element is exposed near the distal end of the extension portion to enable it to directly contact an object to be sensed for temperature by the sensor probe.

2. The low-profile temperature sensor probe of claim 1 wherein the extension portion further comprises an aperture near the distal end of the extension portion; and
wherein the thermistor element is located in the aperture.

3. The low-profile temperature sensor probe of claim 2 further comprising a support cover installed in the aperture that forms at least a portion of a pocket surrounding the thermistor element; and
wherein the support cover positions the thermistor element relative to a first side surface of the extension portion.

4. The low-profile temperature sensor probe of claim 3 wherein the support cover comprises a resilient thermoplastic material.

5. The low-profile temperature sensor probe of claim 3 wherein the support cover and the aperture combine to form a pocket surrounding the thermistor element.

6. The low-profile temperature sensor probe of claim 3 wherein the support cover positions the thermistor element so that it slightly protrudes from the first side surface of the extension portion.

7. The low-profile temperature sensor probe of claim 2 wherein the body comprises a resilient thermoplastic material.

8. The low-profile temperature sensor probe of claim 7 wherein the body comprises a nylon injection molding material.

9. A low-profile temperature sensor probe comprising:
a probe circuit substantially encompassed by an integral, resilient, dielectric body;
wherein the probe circuit comprises a thermistor having two first insulated lead wires, two second insulated lead wires, and a resilient protective cover located around the first insulated lead wires, wherein each first lead wire is electrically connected to a respective second lead wire to create two first lead wire/second lead wire connections, the first lead wire/second lead wire connections being electrically isolated from one another;
wherein the body comprises an extension portion that generally extends along a longitudinal axis of the sensor probe from a first proximal end to a second distal end, the extension portion comprising a first surface and an aperture near its distal end; and
wherein the thermistor is located in the aperture and positioned relative to the first surface such that it directly contacts an object to be sensed for temperature when the sensor probe is in use.

10. A low-profile temperature sensor probe of claim 9 wherein the probe circuit further comprises a pair of terminals, wherein each terminal electrically connected to a respective second lead wire to create two terminal/second lead wire connections; and
wherein the body further comprises a connector block portion integrally formed with the extension portion, the connector block portion housing the electric terminals and configured to accommodate a plug-in type electrical connector.

11. A low-profile temperature sensor probe of claim 9 further comprising a first heat-shrinkable, dielectric tubular material surrounding one of the two thermistor lead/second lead wire connections; and
a second heat-shrinkable, dielectric tubular material surrounding both thermistor lead/second lead wire connections and the first tubular material.

12. The low-profile temperature sensor probe of claim 9 further comprising a support cover installed in the aperture that forms at least a portion of a pocket around the thermistor; and
wherein the support cover positions the thermistor relative to the first surface.

13. The low-profile temperature sensor probe of claim 12 wherein the support cover positions the thermistor so that it slightly protrudes from the first surface of the extension portion.

14. The low-profile temperature sensor probe of claim 13 wherein the support cover comprises a resilient thermoplastic material.

15. The low-profile temperature sensor probe of claim 9 wherein the body comprises a resilient thermoplastic material.

16. The low-profile temperature sensor probe of claim 9 wherein the extension portion further comprises one or more second apertures for locating or mounting the sensor probe.

17. The low-profile temperature sensor probe of claim 9 wherein the probe circuit further comprises two terminals, wherein each terminal is electrically connected to a respective second lead wire to create two terminal/second lead wire connections, the terminal/second lead wire connections being electrically isolated from one another.

18. The low-profile temperature sensor probe of claim 9 wherein the second lead wires extend from the body to form part of a wiring harness that connects the sensor probe to a controller monitoring the condition of the sensor probe.

19. A method for manufacturing a low-profile temperature sensor comprising:
providing a thermistor element comprising a thermistor bead and two insulated thermistor leads;
surrounding both thermistor leads with a tubular PTFE material;
providing a pair of insulated lead wires, each having a first end and a second end;
electrically connecting each thermistor lead to the first end of a corresponding lead wire to create a pair of first electrical connections;
surrounding one thermistor lead/lead wire connection with a first heat shrinkable, dielectric, tubular material;
surrounding the other thermistor lead/lead wire connection and the first heat shrinkable, dielectric, tubular material with a second heat shrinkable, dielectric, tubular material;
providing a pair of terminals;
electrically connecting each terminal to a second end of a corresponding lead wire to create a pair of second electrical connections;
encompassing the first and second electrical connections and the lead wires with a dielectric, thermoplastic material to create a flexible extension portion including an aperture near a distal end of the extension portion, and wherein the thermistor element is located within the aperture;
inserting a support element in the aperture to position the thermistor bead relative to a first surface of the extension portion such that the thermistor bead protrudes from the first surface.

20. A method for manufacturing a low-profile temperature sensor including a circuit comprising a thermistor element and lead wires, the method comprising:
surrounding two insulated thermistor leads of the thermistor element with a protective, resilient material;
electrically connecting each of the two insulated thermistor leads of the thermistor element to a corresponding one of two lead wires to create two thermistor lead/lead wire connections;
electrically isolating the thermistor lead/lead wire connections from one another;
overmolding the thermistor lead/lead wire connections with a resilient, dielectric thermoplastic material to encompass the thermistor lead/lead wire connections and forming a body comprising an extension portion, the extension portion including a first surface and an aperture in which the thermistor element is located; and
positioning the thermistor element relative to the first surface of the extension portion such that the thermistor element protrudes from the first surface.

21. The method for manufacturing a low-profile temperature sensor of claim 20, wherein the step of positioning comprises inserting a support element in the aperture.

22. The method for manufacturing a low-profile temperature sensor of claim 20, further comprising electrically connecting a terminal to each of the lead wires at an end of the lead wires opposite to the thermistor lead/lead wire connection to create two terminal/lead wire connections.

23. The method for manufacturing a low-profile temperature sensor of claim 22, wherein the step of overmolding encapsulates the terminal/lead wire connections; and
the body further comprises a connector block portion housing the electric terminals and configured to accommodate a plug-in type electrical connector.
